(19) United States
(12) Patent Application Publication
(10) Pub. No.: US 2010/0200537 A1
(43) Pub. Date: Aug. 12, 2010

(54) Nano-patterned metal electrode for solid oxide fuel cell

(76) Inventors: Young Beom Kim, Stanford, CA (US); Yi Cui, Sunnyvale, CA (US); Ching-Mei Hsu, Stanford, CA (US); Steve T. Connor, Palo Alto, CA (US); Friedrich B. Prinz, Woodside, CA (US)

Correspondence Address: LUMEN PATENT FIRM, 350 Cambridge Avenue, Suite 100, PALO ALTO, CA, 94306, US

(21) Appl. No.: 12/653,968

(22) Filed: Dec. 17, 2009

Related U.S. Application Data
(60) Provisional application No. 61/203,046, filed on Dec. 17, 2008.

(51) Int. Cl. H01M 4/88; C23C 14/34

(52) U.S. Cl. 216/13; 427/115; 427/560; 204/192.17; 977/948

(57) ABSTRACT

The current invention provides a method of fabricating nano-pore structured dense Pt electrodes using particle masking and LB deposition methods. The pore size and TPB density are easily tunable by changing initial size of the masking silica particles and the spacing between them. Compared to the solid oxide fuel cell MEAs with porous Pt electrode deposited by conventional DC sputtering method, fuel cell MEAs with the nano structured electrodes fabricated according to the current invention showed thermal and microstructural stability and superior I-V performance at 400˜450° C. Also, EIS spectra showed significant improvement in the oxygen reduction kinetics by increasing the density of charge transfer sites at the TPB. A nearly linear scaling relationship between TPB density and fuel cell performance was also demonstrated.

### CROSS-REFERENCE TO RELATED APPLICATIONS

This application is cross-referenced to and claims the benefit from U.S. Provisional Application 61/203046 filed Dec. 17, 2008, and which are hereby incorporated by reference.

### FIELD OF THE INVENTION

The present invention relates generally to fuel cell electrodes. More particularly, the invention relates to a method of fabricating electrode geometries to maximize their triple phase boundary and structural thermal stability for improved fuel cell performance.

### BACKGROUND

Solid oxide fuel cells (SOFC) are efficient energy conversion devices that are being developed for practical applications. Due to the large activation energy (˜1 eV) for oxide ion transport in the solid oxide electrolyte, SOFCs usually are operated at elevated temperatures (800˜1000° C.) to obtain practically meaningful fluxes. Typically, an SOFC element is made of a yttria-stabilized zirconia electrolyte layer with a mixed conducting ceramic cathode such as La₁₋ₓSrₓCo_{1-y}Fe_{y}O₃ (LSCF) and La₁₋ₓSrₓMnO_{3-!″} (LSM) and a cermet anode such as Ni/YSZ.

Operation of SOFCs at elevated temperatures may be desirable for enhanced kinetics and transport purposes, but pose serious challenges in microstructural and thermal stability, seal integrity, aging and degradation, thermal cycling, and cost of materials and fabrication. To mitigate some of these problems, most of the recent efforts have been aimed towards lowering the operating temperature of SOFCs to intermediate temperature regime of 700-800° C., i.e., IT-SOFCs. Although oxygen chemical diffusion in these mixed conducting ceramics is relatively fast at elevated temperatures, they exhibit a significant drop in their catalytic properties at lower temperatures that lead to increased activation loses for IT-SOFCs.

Solid Oxide fuel cell charge transfer takes place at the reaction sites know as the triple phase boundary (TPB), where the gas, catalytic electrode, and the electrolyte are all in physical contact. To enhance fuel cell performance, it is desirable to maximize the TPB. The TPB has a finite width usually determined by the microstructure and grain size, porosity, material properties, and the operating conditions. What is needed is a fabrication technique that generates well-defined TPB geometry, and maximizes the TPB as well as a structural thermal stability for improved and optimized performance of the fuel cell.

### SUMMARY OF THE INVENTION

The present invention provides a method of fabricating a solid oxide fuel cell nano-pore structured electrode. The method includes depositing spherical nano-particles on a substrate, where the substrate has an electrolyte material, deposited an electrode material on the spherical nano-particles and on the substrate, and removing the nano-particles from the substrate, where a nano-pore structured electrode is disposed on the substrate.

In one aspect of the invention the spherical nano-particles include silica spherical nano-particles.

According to another aspect of the invention, the electrolyte material us YSZ.

In a further aspect, the electrode material includes Pt.

In yet another aspect, the electrode material is deposited using a method such as DC sputtering or CVD.

According to one aspect, the substrate material is not etched.

In a further aspect of the invention, the spherical nano-particles are reduced in size by plasma etching, where the plasma etching is done before the depositing the electrode material.

According to one embodiment, the nano-particles have a diameter size in the range of 50 nm to 900 nm.

In another aspect of the invention, the deposited electrode material has a thickness in a range of 5 nm to 200 nm.

The method of fabricating a solid oxide fuel cell nano-pore structured electrode of claim 1, wherein the spherical nano-particles are removed by sonication.

In yet another aspect, depositing spherical the nano-particles on a substrate includes using a Langmuir-Blodgett deposition method, where the Langmuir-Blodgett deposition method includes injecting silica nano-particles on a water surface, forming a closed-packed monolayer of the silica nano-particles, inputting the substrate in the water, and removing the substrate from the water at a constant speed, where the substrate is coated with a closed-packed pattern of the silica nano-particles.

### BRIEF DESCRIPTION OF THE FIGURES

The objectives and advantages of the present invention will be understood by reading the following detailed description in conjunction with the drawing, in which:

FIGS. 1(a)-(b) show different sizes of particles used as a mask for patterning of the Pt layer according to the present invention.

FIGS. 2(a)-2(e) show the steps of transferring the spherical particles to the surface of the substrate according to the present invention.

FIGS. 3(a)-3(d) show the steps of fabricating nano-pore patterned dense Pt electrode according to the present invention.

FIGS. 4(a)-4(b) show two exemplary nano-pore patterned dense Pt electrodes with different pore sizes according to the present invention.

FIGS. 5(a)-5(d) show a comparison of the change in the morphology of the DC sputtered porous Pt electrodes versus nano-pore patterned dense Pt electrodes before and after fuel cell testing according to the present invention.

FIG. 6 shows graph comparing the fuel cell performance of sputtered Pt electrodes with patterned Pt electrodes according to the present invention.

FIG. 7 shows a comparison of the I-V performance at 450° C. of a SOFC MEA featuring a nano-patterned Pt electrode at the cathode of approximately 400 nm diameter pore size according to the current invention with a MEA with DC sputtered porous Pt electrode.

FIG. 8 shows the fuel cell performance comparison of two samples with different TPB densities according to the current invention.

FIG. 9 shows a comparison of the electrochemical impedance spectroscopy (EIS) spectra at 450° C. of SOFC samples with nano-patterned Pt cathodes of different pore sizes according to the present invention.

### DETAILED DESCRIPTION OF THE INVENTION

Although the following detailed description contains many specifics for the purposes of illustration, anyone of ordinary skill in the art will readily appreciate that many variations and alterations to the following exemplary details are within the scope of the invention. Accordingly, the following preferred embodiment of the invention is set forth without any loss of generality to, and without imposing limitations upon, the claimed invention.

The current invention is a fabrication technique that generates well-defined TPB geometry, and maximizes the TPB as well as a structural thermal stability for improved and optimized performance of the fuel cell. Initially, a mask is created from spherical silica particles by chemical synthesis using tetraethyl orthosilicate (TEOS). The initial particle sizes are controllable from 50 nm to 900 nm in diameter. For the transfer of these particles on to the substrate, a Langmuir-Blodgett (LB) trough is used. This involves transferring the spherical particles as a film from the surface of a liquid inside the LB trough by steadily withdrawing the solid substrate from the liquid at a finite rate. By using this method, a closed packed monolayer of silica particles can be created, which can maximize the density of the TPB on the desired substrates.

For making solid oxide fuel cell (SOFC) samples, these closed packed silica particles are deposited on to a yttria stabilized zirconia (YSZ) electrolyte substrate and deposited 80 nm of Pt electrode utilizing an sputtering or evaporation technique. Removal of the particles by sonication yields a nanostructured electrode with well-defined pore geometry that enables the study of TPB geometric effect in a systematic and controlled manner.

Usually, a sputtered porous Pt electrode is employed to increase the TPB for improved fuel cell performance. However, this sputtered electrode is not thermally stable at high operation temperature, and most importantly, it is hard to define the exact geometry and microstructure of the TPB. In addition, if the pore size of the electrode layer is too small, the finite TPB width of the pores may overlap excessively, decreasing full utilization of the reaction sites. By using the electrode patterning technique of the current invention for solid oxide fuel cell fabrication, thermal stability of the electrode can be improved and be maximized to optimize the performance of the fuel cell.

The Triple Phase Density (TPB) can be controlled by varying the initial spherical mask sizes to find an optimal value of the fuel cell performance. Since TPB widths are different from substrate materials and operating conditions, it is necessary to find an optimal size for each substrate material. That is also a reason why this technique is powerful because the geometry of TPB is easily controlled and it is thermally stable at high operating temperature. The use of the metal electrode in the current invention for a solid oxide fuel cell is a new approach.

The current invention provides a fabrication method of a solid oxide fuel cell nano-pore structured electrode and demonstrates testing of a model electrode to study geometric effects at well-defined triple phase boundaries (TPB) in solid oxide fuel cells (SOFC), using silica particle masking and Langmuir-Blodgett deposition. Electrochemical behavior of dense platinum cathodes are patterned into close-packed circular openings of 300-400 nm in diameter through which the underlying yttria-stabilized zirconia (YSZ) electrolyte was exposed to the gas environment were studied at 450° C. These nano-structured cathodes exhibited better structural integrity and thermal stability at operating temperatures than their porous sputtered Pt counterparts. 100 μm-thick 8% polycrystalline YSZ was used as the electrolyte in these tests. It is shown that cathode impedances obtained from EIS Nyquist spectra as well as the maximum power densities scaled almost linearly with TPB density, i.e., higher TPB density resulted in better fuel cell performance.

The current invention reduces the operating temperature of SOFCs to a regime between 300 and 500° C. by employing thin film structures of the YSZ electrolyte and electrodes. Use of mixed conducting ceramics and cermets for such low temperature (300-500° C.) SOFCs (LT-SOFCs) are not meaningful due to significant losses from large overpotentials at the electrodes. Hence, the current invention uses platinum electrode material, which not only enhances the fuel cell performance but also provides a stable and geometrically well-defined platform to examine the triple phase boundary effects in SOFCs. In particular, increasing the oxygen reduction reaction at the cathode is critically important in order to minimize the activation loss and to improve the fuel cell performance at such low temperatures.

The charge transfer reaction at the cathode involves reduction of oxygen at the electrochemical reaction sites commonly known as the triple phase boundary (TPB), where the gas, catalytic cathode, and the electrolyte are all in physical contact. Due to relatively high activation energy of >1.5 eV for the oxygen reduction reaction, it is generally agreed that the processes at the cathode govern the overall behavior of SOFCs even at elevated temperatures. To enhance fuel cell performance, the current invention improves the reaction kinetics at the cathode. This is achieved by maximizing the TPB. Typically, use of an unstructured DC sputtered porous Pt electrode can increase the TPB for improved fuel cell performance. However, due to Ostwald ripening, sputtered Pt electrodes may suffer microstructural coarsening and degradation and are generally not thermally stable at high operation temperature. Most importantly, however, it is difficult to quantify and define the exact geometry, scale and nanostructure of the TPB. This makes it difficult to quantitatively investigate the rate processes at the TPB.

The present invention provides a new patterning technique for a fabrication method of Pt electrodes with easily tunable and well-defined TPB geometry. This method also provides the ability to maximize the TPB in a controllable manner. Furthermore, the present invention demonstrates superior microstructural and thermal stability of such patterned electrodes for improved and consistent SOFC performance.

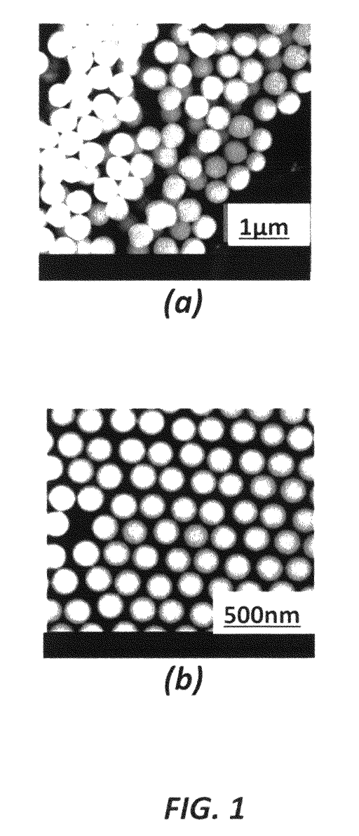

According to the current invention, an exemplary fabrication of a nano-pore patterned dense Pt electrode is on the cathode side of the SOFC. Initially, a mask is created from spherical silica particles by chemical synthesis using tetraethyl orthosilicate (TEOS). The TEOS molecules are easily converted to silicon dioxide via a series of condensation reactions. The rates of conversion are sensitive to the presence of either acidic or basic catalysts. Size of the spherical silica particles can be controlled by varying the amount of TEOS and catalyst materials. Thus, different sizes of particles are used as a mask for subsequent patterning of the Pt layer as shown in FIGS. 1(a)-(b), where FIG. 1(a) shows 400 nm in diameter and FIG. 1(b) shows 600 nm in diameter as an example.

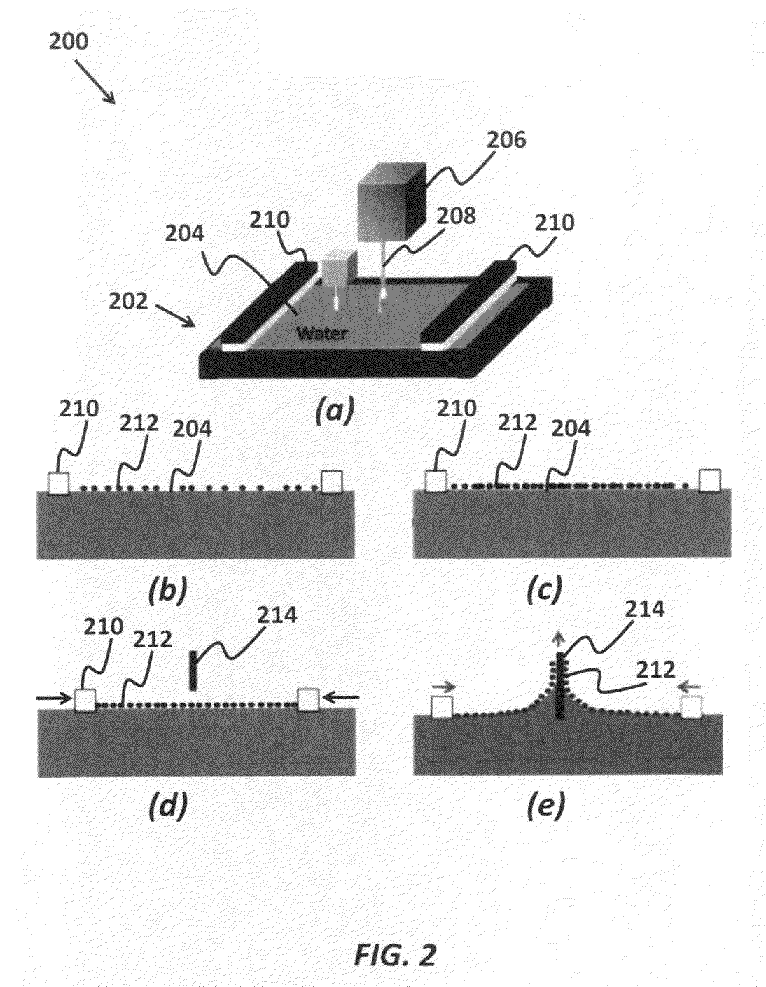

The spherical silica particles were transferred onto a desired substrate using a Langmuir-Blodgett (LB) trough technique. In this example, the substrate is a 100 μm-thick 8% yttria-stabilized zirconia (YSZ) polycrystalline wafer. The transfer process involved removing the spherical particles as a film from the surface of a liquid inside the LB trough by steadily withdrawing the electrolyte substrate from the liquid at a finite rate. FIGS. 2(a)-2(e) show the steps of transferring the spherical particles to the surface of the substrate 200. Initially, FIG. 2(a) shows the LB trough 202 is filled with DI water 204, where a dipping controller 206 and a substrate dipper 208 are shown above the LB trough 202, and compression bars 210 are disposed to traverse along the surface of the water 204. FIG. 2(b) shows the prepared silica particles 212 are introduced on to the surface of the water 204 by slow injection. FIG. 2(c) and FIG. 2(d) show using the compression bars 210 in the trough 202, a monolayer of particles 212 produced at the surface of the water 204. FIG. 2(e) shows the electrolyte substrate 214 is dipped into the trough 202 and pulled out at a constant rate. By using this method, one can create a close-packed monolayer of silica particles, and by appropriately varying the silica particle size can optimize the TPB density on the electrolyte substrate.

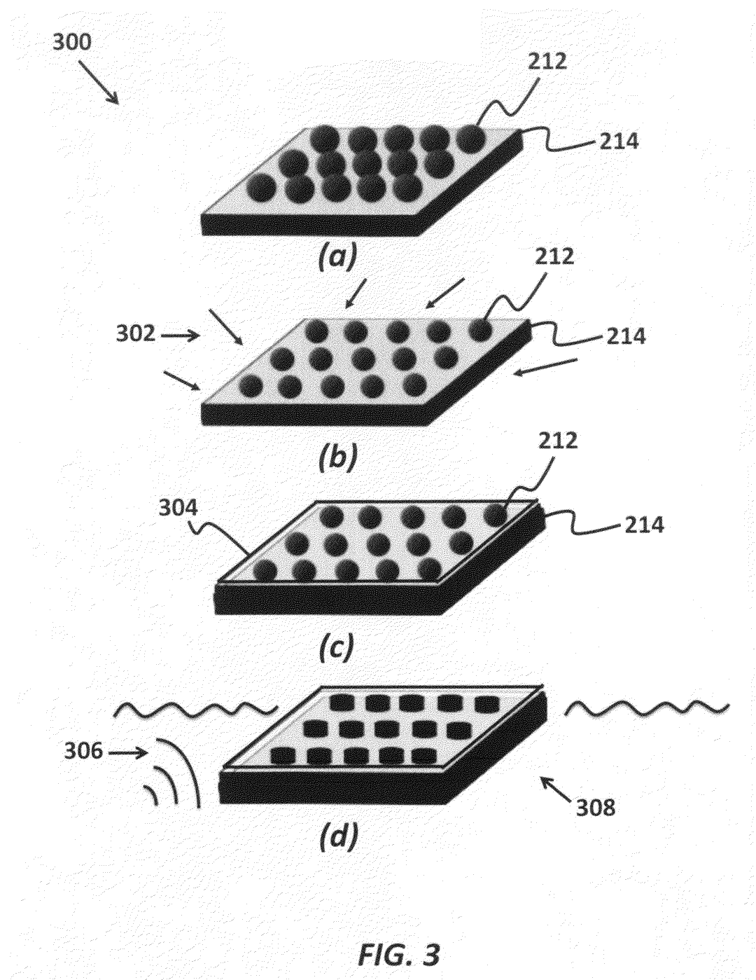

Referring not to FIGS. 3(a)-3(d), which show the steps of fabricating nano-pore patterned dense Pt electrode 300, after forming the monolayer of the particles 212 on the electrolyte substrate 214, the step of anisotropic plasma etching 302 is used to reduce the size of the silica particles 212 in order to provide sufficient room for Pt deposition 304 (see FIG. 3(c)) through the interspacing between the spherical particles 212. Then the particles 212 are removed mechanically from the YSZ substrate 214 using ultra sonication 306, and the fabrication of the SOFC membrane electrode assembly (MEA) 308 is completed.

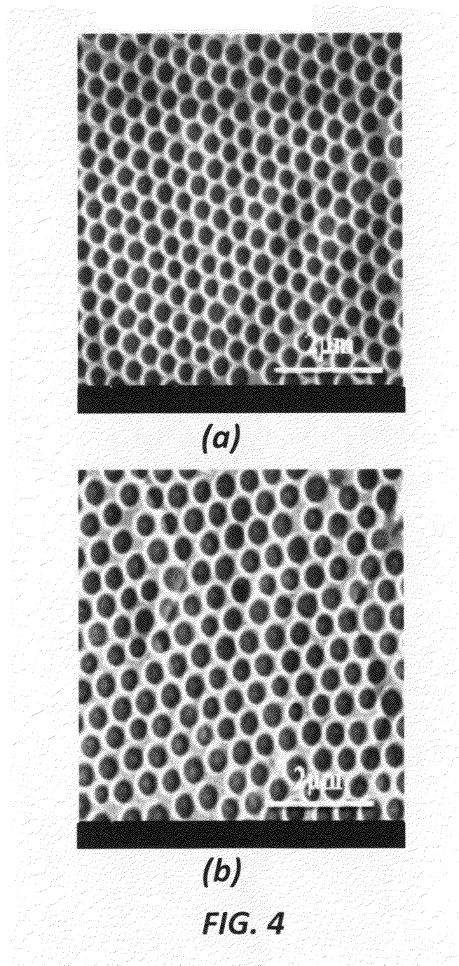

In the following examples, two different sizes of the particles were employed, namely, 410 nm and 330 nm, to make nano-pore structured Pt electrodes with different TPB densities. After forming a monolayer of those particles on the YSZ substrates, 60 nm thick, dense Pt electrode was deposited in between the inter-spacings of the silica particles utilizing DC sputtering technique, where the thickness can be in a range of 5 nm to 200 nm or according to the size of the nano-particles. Removal of particles by ultra sonication yields a patterned Pt electrode layer with well-defined geometry that enables the study of TPB geometric effects in a systematic and controlled manner as shown in FIGS. 4(a) and 4(b), which show nano-pore structured dense Pt electrodes with different pore size and TPB density, 4(a) 300 nm, 4(b) 400 nm. SEM images were taken with same magnification and the image with smaller initial particle size shows the denser pores, which relates to increased TPB density.

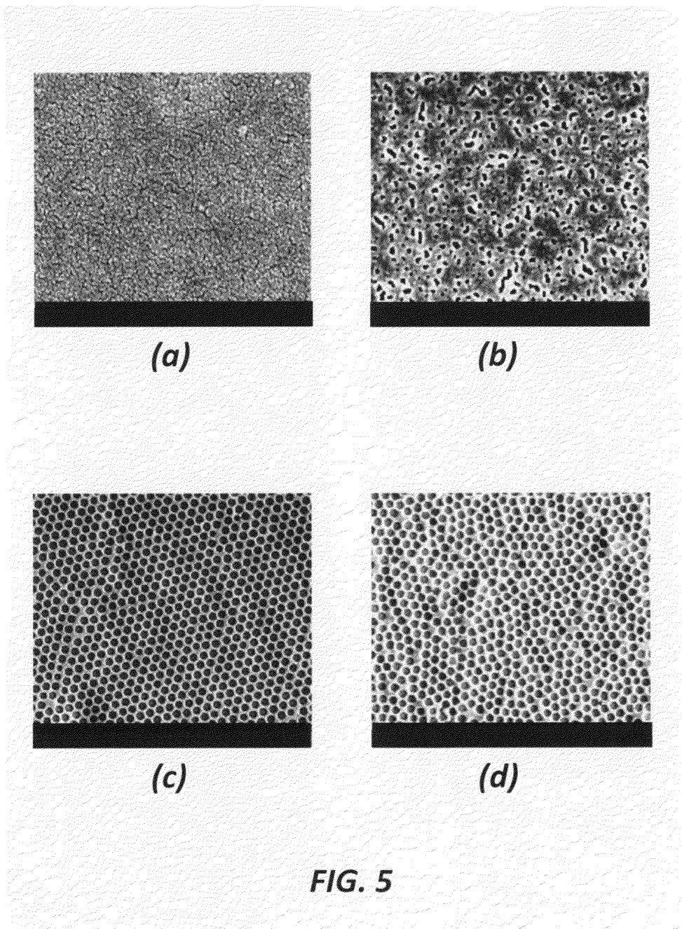

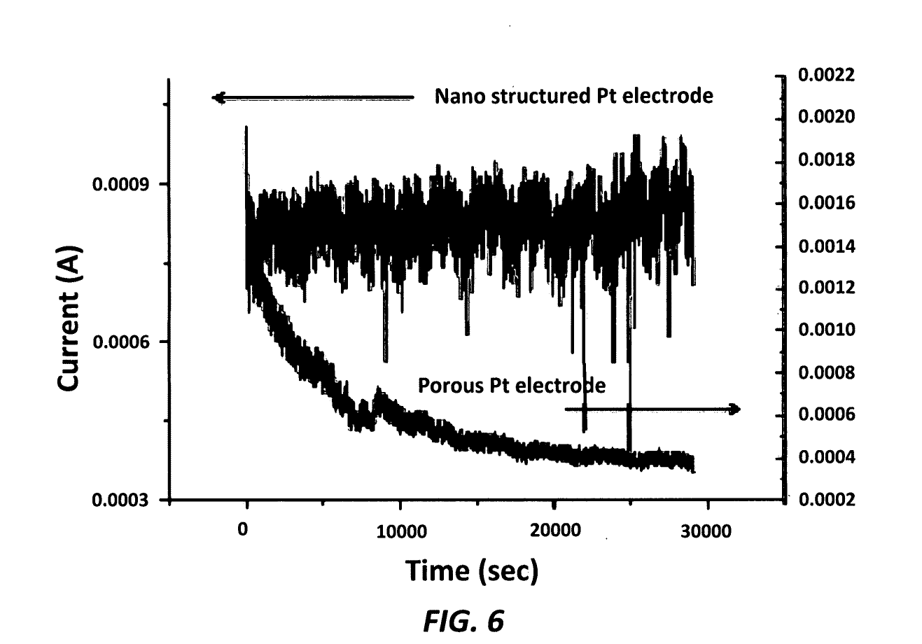

FIGS. 5(a)-5(d) show a comparison of the change in the morphology 500 of the DC sputtered porous Pt electrodes versus nano-pore patterned dense Pt electrodes before and after fuel cell testing according to the present invention. Here, a DC sputtered porous Pt electrode before operating fuel cell is shown in FIG. 5(a), and FIG. 5(b) shows a decrease of TPB due to the degradation of porous Pt after short time (˜30 mins) of operating a fuel cell at elevated temperature. Conversely FIG. 5(c) shows the nano-pore patterned dense Pt electrode of the current invention before operating a fuel cell at elevated temperature, and FIG. 5(d) shows the same nano-pore patterned dense Pt electrode after operating the fuel cell at elevated temperature. It is clear that even at the moderately low (400-450° C.) operating temperature of LT-SOFC, there is significant change taking place in the microstructure of the porous Pt electrode driven by its high surface energy. Due to the visibly evident degradation of the Pt morphology, the decrease in the TPB density leads to a rapid reduction in the fuel cell performance until it seems to stabilize at a low value after a short time. This is shown in FIG. 6, which compares the fuel cell performance of sputtered porous Pt electrodes with patterned Pt electrodes. After completion of the I-V experiments for both samples, the output currents of the two cells were monitored for 12 hours at 500° C. at a constant voltage that corresponds to the peak power density value. Despite the periodic noise in the data that came from the measurement setup, particularly from the temperature controller and the fume hood fan, FIG. 6 indicates a stable performance by the nano-structured Pt electrode, while the current output from the porous Pt cell clearly shows a rapid decay over time. Here, potentioamperometry data at 0.6V compare the behavior of SOFC MEA with porous Pt electrode and SOFC with nano-pore structured Pt electrode. Measurements were conducted for 12 hours continuously at 500° C. Severe performance degradation is observed with porous Pt.

The difference in the performance between the patterned and porous Pt electrodes was supplemented by the SEM images provided in FIG. 5(c) and FIG. 5(d). Unlike the porous Pt cathodes, the patterned Pt morphology indicated no discernable change in the microstructure due to exposure to operating temperatures and testing under load in a SOFC configuration. The results suggest that the nano-patterning method employed in this study helped stabilize the morphology and provided thermal and microstructural stability at the operating temperatures.

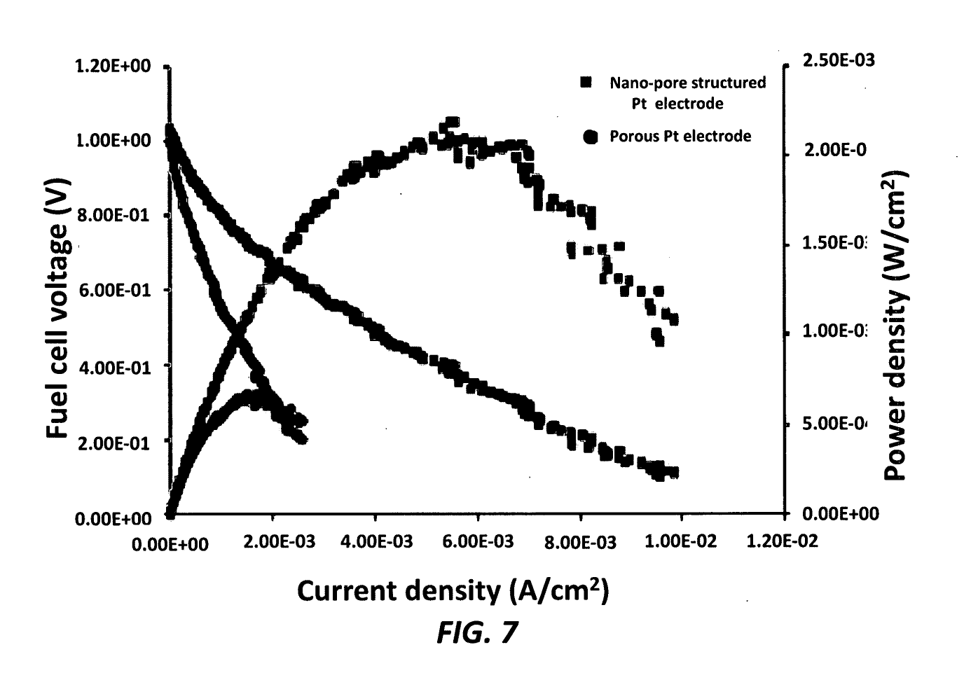

FIG. 7 compares the I-V performance at 450° C. of a SOFC MEA featuring a nano-patterned Pt electrode at the cathode of approximately 400 nm diameter pore size with a MEA with DC sputtered porous Pt electrode. It is clear that the nano-patterned Pt outperforms porous sputtered Pt electrode behavior.

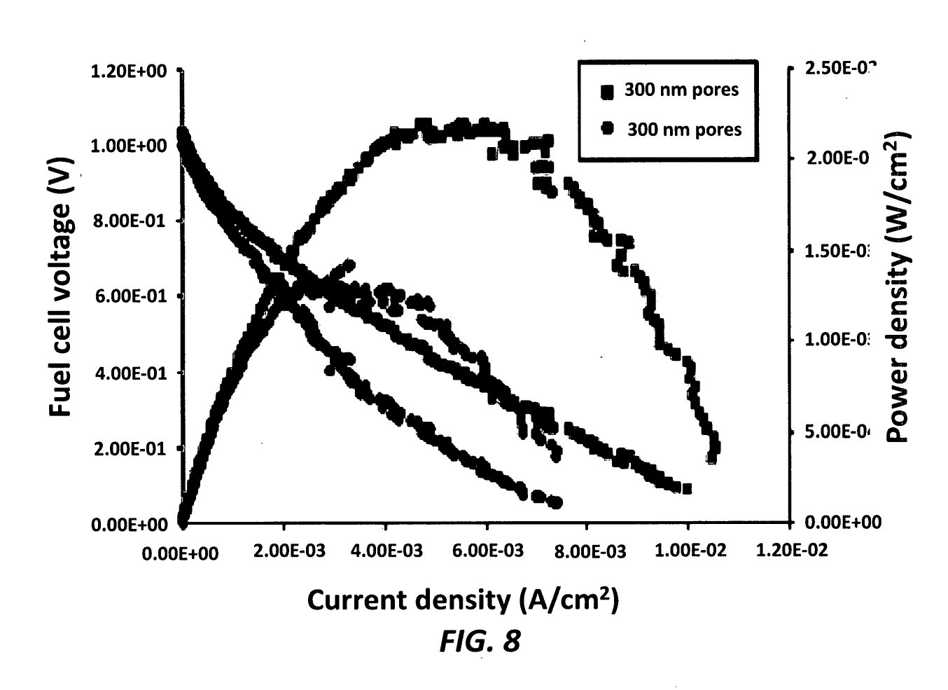

FIG. 8 shows the fuel cell performance comparison of two samples with different TPB densities according to the current invention. The SOFC MEA with denser TPB (pore diameter ˜300 nm) at the cathode shows better performance than the SOFC with coarser (˜400 nm) TPB cathode electrode. Peak power densities and open circuit voltages (OCV) of the 300 nm and 400 nm pore size patterned Pt cathodes are 2.2 mW/cm² and 1.04 V, and 1.4 mW/cm² and 1.01V, at 450° C., respectively. Also the coarser TPB sample shows a larger exponential drop at low current region, indicative of a larger activation loss than the denser TPB sample.

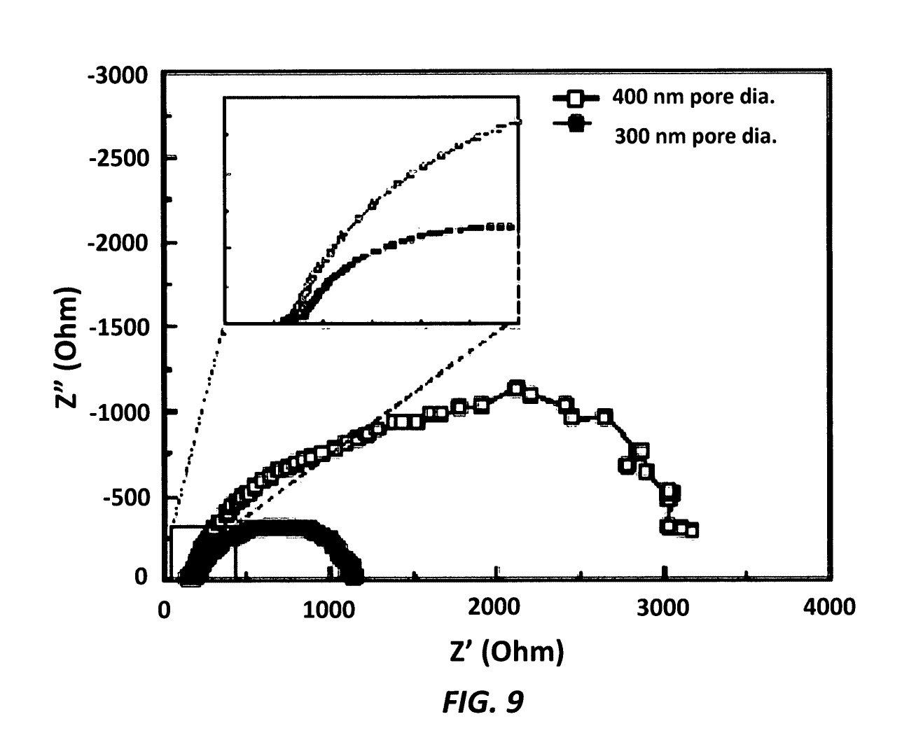

Similarly, FIG. 9 shows a comparison of the electrochemical impedance spectroscopy (EIS) spectra at 450° C. of SOFC samples with nano-patterned Pt cathodes of different pore sizes. Assigning the low-frequency arc in EIS spectra of Pt/YSZ assemblies to the ORR (Oxygen Reduction Reaction) process, one can conclude that the cathode impedance is reduced for the 300 nm pore size Pt electrode due to increased TPB density as compared to the 400 nm pore size Pt having a lower TPB density, and hence, a larger cathode impedance. Clearly, EIS impedance data provided further support for faster or improved oxygen reduction kinetics at the cathode by increasing the TPB density and the charge transfer reaction sites.

Well-defined geometry of the open pores in a close-packed fashion makes it possible to approximate the TPB density (cm/cm²) for a given patterned area, and this is a function of pore diameter and spacing between the pores. With the help of the SEM images, the TPB densities for the two patterned Pt cathodes were approximated. The SOFC sample with the smaller initial diameter of the silica particle showed a factor of 1.8 higher TPB densities than the SOFC sample with the larger size of the starting silica particles. It is interesting to check this scaling factor against cell performance and behavior.

From the EIS spectra for the two samples in FIG. 9, it is possible to determine the cathode resistance, which is related to the charge transfer reaction. The electrode resistance of the coarser TPB SOFC sample (2600 ohms) is a factor of 2.06 higher than the SOFC sample with denser TPB (4260 ohms), corresponding to smaller starting silica particles. Although it number does not perfectly match the ratio of 1.8 between the TPB densities of the two samples, it does suggest within experimental error that the electrode resistance scales almost linearly with the TPB density.

Furthermore, a similar scaling behavior is observed between the TPB density and the peak power densities of the two samples shown in the I-V curves of FIG. 8. Indeed, the ratio of 1.6 between the peak power densities of the two samples agrees within experimental error with the TPB ratio of 1.8 between the two patterned cathode samples, suggesting again a linear scaling law.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. All such variations are considered to be within the scope and spirit of the present invention as defined by the following claims and their legal equivalents.

What is claimed is:

1. A method of fabricating a solid oxide fuel cell nano-pore structured electrode, comprising:
a. depositing spherical nano-particles on a substrate, wherein said substrate comprises an electrolyte material;
b. depositing an electrode material on said spherical nano-particles and on said substrate; and
c. removing said nano-particles from said substrate, wherein a nano-pore structured electrode is disposed on said substrate.

2. The method of fabricating a solid oxide fuel cell nano-pore structured electrode of claim 1, wherein said spherical nano-particles comprise silica spherical nano-particles.

3. The method of fabricating a solid oxide fuel cell nano-pore structured electrode of claim 1, wherein said electrolyte material comprises YSZ.

4. The method of fabricating a solid oxide fuel cell nano-pore structured electrode of claim 1, wherein said electrode material comprises Pt.

5. The method of fabricating a solid oxide fuel cell nano-pore structured electrode of claim 1, wherein said electrode material is deposited using a method selected from the group consisting of DC sputtering, and CVD.

6. The method of fabricating a solid oxide fuel cell nano-pore structured electrode of claim 1, wherein said substrate material is not etched.

7. The method of fabricating a solid oxide fuel cell nano-pore structured electrode of claim 1, wherein said spherical nano-particles are reduced in size by plasma etching, wherein said plasma etching is done before said depositing said electrode material.

8. The method of fabricating a solid oxide fuel cell nano-pore structured electrode of claim 1, wherein said nano-particles have a diameter size in the range of 50 nm to 900 nm.

9. The method of fabricating a solid oxide fuel cell nano-pore structured electrode of claim 1, wherein said deposited electrode material has a thickness in a range of 5 nm to 200 nm.

10. The method of fabricating a solid oxide fuel cell nano-pore structured electrode of claim 1, wherein said spherical nano-particles are removed by sonication.

11. The method of fabricating a solid oxide fuel cell nano-pore structured electrode of claim 1, wherein said depositing spherical nano-particles on a substrate comprises using a Langmuir-Blodgett deposition method, wherein said Langmuir-Blodgett deposition method comprises:
a. injecting silica nano-particles on a water surface;
b. forming a closed-packed monolayer of said silica nano-particles;
c. inputting said substrate in said water; and
d. removing said substrate from said water at a constant speed, wherein said substrate is coated with a closed-packed pattern of said silica nano-particles.
